(19) United States
(12) Patent Application Publication
(10) Pub. No.: US 2025/0003076 A1
(43) Pub. Date: Jan. 2, 2025

(54) MODULAR HEATING JACKET WITH REMOLDABLE INSULATOR

(71) Applicant: Applied Materials, Inc., Santa Clara, CA (US)

(72) Inventors: Andrea Leoncini, Singapore (SG); Yi Kun Kelvin Goh, Singapore (SG)

(73) Assignee: Applied Materials, Inc., Santa Clara, CA (US)

(21) Appl. No.: 18/214,918

(22) Filed: Jun. 27, 2023

(51) Int. Cl. C23C 16/458; C23C 16/44; C23C 16/46

(52) U.S. Cl. CPC C23C 16/4586; C23C 16/4412; C23C 16/46

(57) ABSTRACT

Embodiments of the disclosure relate to heating jackets comprising a reformable insulator. The insulator may be shaped to conform to the shape of a vapor deposition precursor delivery system, or a portion thereof, and subsequently reformed to a different vapor deposition precursor delivery system, or a portion thereof. Some embodiments of the disclosure combine multiple heating modules to form a heating jacket. The heating modules contain a flexible heating element and an insulating, protective cover.

### TECHNICAL FIELD

Embodiments of the disclosure generally relate to modular heating jackets, methods of forming and methods of use. In particular, embodiments of the disclosure relate to modular heating jackets comprising a remoldable insulator.

### BACKGROUND

Chemical delivery systems for semiconductor manufacturing may utilize solid or liquid precursor ampoules which are heated during precursor delivery to aid in volatilizing the precursor for delivery into the processing chamber. There is also a need to heat the delivery lines which provide the precursor from the ampoule to the processing chamber.

The precursors may be supplied in ampoules of various sizes which are connected to a series of delivery lines including various valves and fittings depending on the ampoule shape, ampoule input/output position, orifice sizes, etc. Given these variations, it is commonly required to reconfigure the lines, valves, fittings, etc. when switching precursor ampoules or chambers.

Accordingly, it is difficult to heat the precursor delivery lines as they are often oddly shaped and/or arranged and change arrangements frequently. Additionally, while there are some standardized heaters for common ampoule shapes, not all of these heaters work together with additional heaters to provide uniform temperatures within the delivery system.

Therefore, there is a need for a heater module which can be shaped and reshaped to provide uniform heating of vapor deposition precursor delivery systems, including ampoules, lines, valves and fittings.

### SUMMARY

One or more embodiments of the disclosure are directed to heater jacket module comprising a first layer including a moldable insulator material configured to conform to a shape of a plurality of lines, valves and/or fittings connected to a vapor deposition precursor delivery system; a second layer over the first layer and including a flexible heating element configured to conform to the shape of the plurality of lines, valves and/or fittings; and a third layer over the second layer and including an electrically insulting and flame retardant cover surrounding the flexible heating element and the moldable insulator.

Another embodiment pertains to a method of forming a heat jacket insulator, the method comprising activating a moldable insulator material; conforming the moldable insulator material to a first plurality of lines, valves and/or fittings comprising a first shape to form a first shape-conformed insulator; and solidifying the first shape-conformed insulator to the first shape.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a cross sectional view of an exemplary vapor deposition precursor delivery system;

FIG. 2 illustrate a modular heating jacket for the vapor deposition precursor delivery system of FIG. 1 in accordance with one or more embodiments of the disclosure; and

FIG. 3 illustrates a process flow for forming a modular heating jacket with a formable insulator in accordance with one or more embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

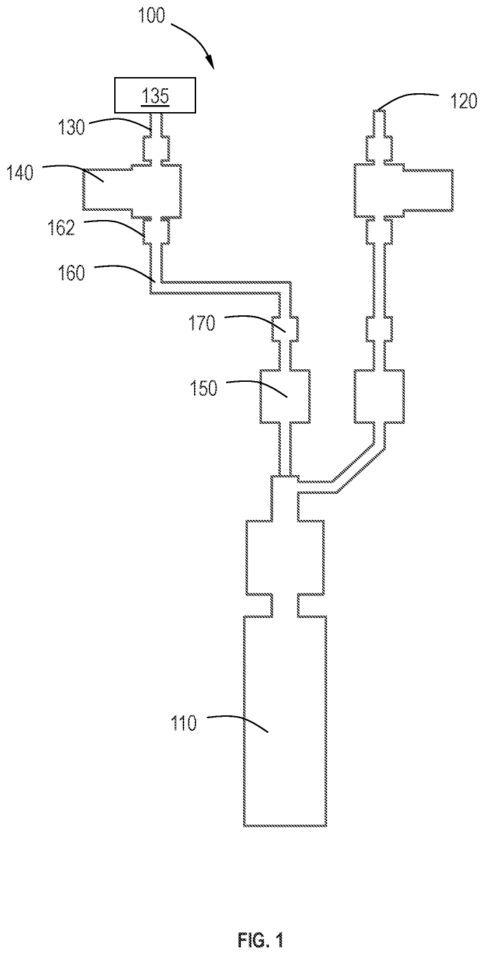

FIG. 1 illustrates a vapor deposition precursor delivery system 100 according to one or more embodiment of the disclosure. The precursor is stored in the ampoule 110. A carrier or diluent gas is provided through an input 120, flows through the system entraining precursor as it passes through the ampoule 110, and exits the system through an output 130 to a vapor deposition processing chamber 135. As used herein, “vapor deposition processing chamber” and “vapor deposition” refer to processes that involve the delivery of precursor vapors to form films on substrates, for example semiconductor wafers. Vapor deposition may include chemical vapor deposition, cyclical vapor deposition and atomic layer deposition.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors. Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

The exemplary system illustrated in FIG. 1 also includes one or more pneumatic valves 140, one or more manual valves 150, a plurality of gas lines 160, and connectors 170. In some embodiments, the connectors include VCR (vacuum coupling radius) fittings 162. VCR fittings 162 and the gas lines 160 to which they are connected to generally have a very small diameters, typically ranging from 1.8 to 15 mm in inner diameter, and smaller diameter VCR fittings 162 and gas lines 160 are very difficult to insulate with conventional heating jackets. Accordingly, existing heating jackets are not able to heat and contact the gas lines 162. The heater jacket modules 210 described according to one or more embodiments comprising the first shape-conformed insulator 320 enables the heater jacket module 210 to properly heat and contact small diameter gas lines having diameters between 1.8 and 15 mm.

While not wishing to be bound by any particular arrangement, according to one or more embodiments, in an effort to minimize the interior volume and space requirement of the vapor deposition precursor delivery system 100, the plurality of gas lines 160 are often shaped at odd angles to form a vapor deposition precursor delivery system 100 with an overall odd shape. “Odd angle” refers to a variety of angles that can include acute, obtuse and right angles. An overall “odd shape” refers to a complex shape that is not a simple geometric shape such as cylindrical, spherical, square in cross-section or rectangular in cross-section. A vapor deposition delivery system comprising a complex shape according to one or more embodiments comprises more than two angled features (including connections, lines, ampoules, etc.), for example three, four, five, six, seven, eight, nine, ten or more than ten angled features.

One or more embodiments of the disclosure relate to a heater jacket module which can advantageously be adapted to the complex shape of any vapor deposition precursor delivery system. Some embodiments further advantageously provide a modular heater jacket which can be remolded to fit a differently shaped and/or uniquely shaped vapor deposition precursor delivery system.

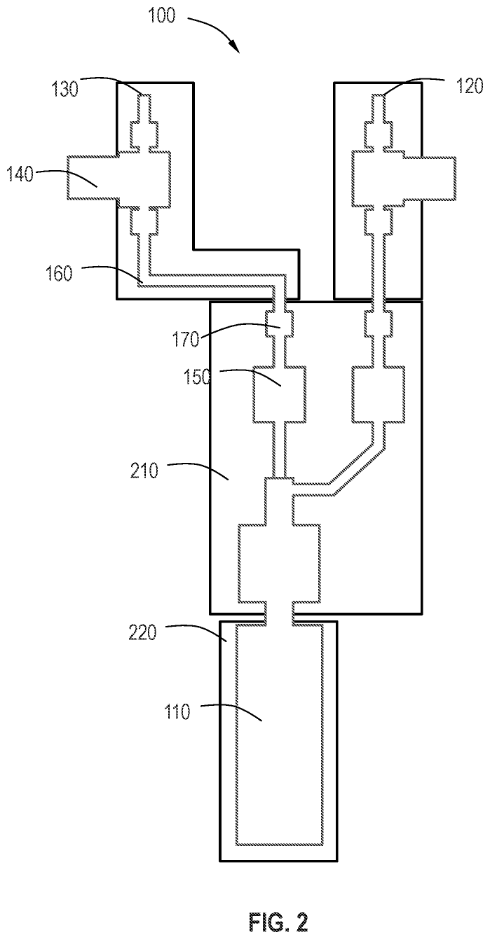

With reference to FIG. 2, the vapor deposition precursor delivery system 100 of FIG. 1 is shown with a modular heater jacket applied according to one or more embodiments. FIG. 2 illustrates that the vapor deposition precursor delivery system may be heated by more than one heater jacket module 210. While the elements of the vapor deposition precursor delivery system 100 are shown in FIG. 2, the disclosed heater jackets may cover only one side of the vapor deposition precursor delivery system 100 (as shown) or may cover both sides of the vapor deposition precursor delivery system 100. In those embodiments where the disclosed heater jackets only cover one side of the vapor deposition precursor delivery system, the other side may be covered by an insulative material or left exposed for better temperature control and/or operation.

While not illustrated in FIG. 2, the disclosed modular heating jackets may contain openings on the edge of the heater jacket to insert and accommodate valve handles or other attachments to the vapor deposition precursor delivery system 100. In these embodiments two modules may be joined together to surround the handle extension or other attachment.

FIG. 2 also illustrates an ampoule heater 220. The ampoule heater 220 may comprise a heater jacket module as disclosed herein. Alternatively, the ampoule heater may comprise a purpose-specific ampoule heater as commonly known and used in the art.

In one or more embodiments, the heater jacket module comprises a first layer including moldable insulator material, a second layer over the first layer and including a flexible heating element and a third layer over the second layer and including a cover. As used in this disclosure and the appended claims, the term “over”, with respect to a layer, includes the layer being directly in contact with another layer, as well as there being one or more intervening between the layer that is over another layer. Thus, in some embodiments, the phrase “over the layer” is intended to include one or more underlayers. In other embodiments, the phrase “directly over” refers to a layer or a film that is in direct contact with another layer, with no intervening layers. Thus, the phrase “a first layer directly over the second layer” refers to the first layer in direct contact with the second layer with no layers in between.

The moldable insulator material is configured to conform to the shape of a plurality of lines, valves and/or fittings of a vapor deposition precursor delivery system having a complex shape. Thus in some embodiments, “moldable” refers to the ability of a material to conform to or assume the shape of a portion of or an entire vapor deposition precursor delivery system. “Remoldable” refers to the ability to re-shape the moldable insulator material to a different shape, for example a differently shaped vapor deposition precursor delivery system. The flexible heating element adapts to the shape of the moldable insulator material (i.e., the shape of the plurality of lines, valves and/or fittings). The cover surrounds the moldable insulator material and the flexible heating element. In some embodiments the cover is electrically insulating. In some embodiments the cover is flame retardant. In some embodiments, the cover is both electrically insulating and flame retardant.

In some embodiments, the moldable insulator material comprises a reformable ceramic. Accordingly, in some embodiments, a reformable ceramic material may be conformed to one shape, then reformed to conform to another shape. In some embodiments, the reformable ceramic comprises a ceramic material that is capable of being activated, formed, solidified, reactivated, and reformed. In some embodiments, the ceramic material is activated/reactivated by wetting the material with water. A used herein “activated” and “activating” refers to causing a sheet of insulator material become moldable and/or remoldable, for example by contacting the reformable material with water. In some embodiments, the ceramic material is solidified by heating the formed ceramic material. A non-limiting example of a remoldable ceramic material is available from McMaster-Carr, Robbinsville, NJ. Moldable ceramic sheets available from McMaster-Carr® are rigid when dry, and the sheets become formable into any shape when wetted by water, including a complex shape. A remoldable material can be molded multiple times until exposed to heat, which causes them to become rigid again. Such moldable ceramic sheets have a working and stable temperature range of −120° F. to 2730° F., a heat flow rate of 1.2 Btu @ 1200° F. and a density of 75 lbs./cu. ft. As used herein, “remoldable” and “reformable” refer to a mass of material such as moldable ceramic insulation sheets that are configured to molded or formed into shapes more than once. Another example of a remoldable or reformable material comprises shape memory polymers, which have the ability to adjust their stiffness, form a temporary shape, and recover the permanent shape upon imposing an appropriate stimulus.

In some embodiments, the flexible heating element comprises a resistive heating element comprising wires filaments, braids, woven fabric, unidirectional fabric or interwoven fabric configured to generate heat by application of electrical power. In some embodiments, the flexible heating element comprises a sheet or a mat of material such as a carbon fiber mat. In some embodiments, the flexible heating element further comprises electrodes to transfer an electrical current from a power supply to the flexible heating element. In some embodiments, the flexible heating element further comprises a controller connected to the electrodes and the power supply and configured to regulate the temperature of the flexible heating element, which in turn regulates the temperature of the components (e.g., ampoule and lines) of the vapor deposition precursor delivery system. In some embodiments, the controller is also connected to the vapor deposition precursor delivery system and is further configured to control the temperature of the flexible heating element in response to the temperature of the vapor deposition precursor delivery system, which can be monitored by a thermometer, thermocouple, etc.

In some embodiments, the cover is electrically insulating and/or flame retardant. In some embodiments, the cover comprises a durable material, for example, an aromatic polyamide fabric such as an aramid fabric, for example, Kevlar. In some embodiments, the cover comprises a heating cover and an insulating cover. The heating cover covers the exterior surface of the flexible heating element, and the insulating cover covers the exterior surface of the moldable insulator. In some embodiments, the heating cover and the insulating cover are joined by a fastener. In some embodiments, the fastener is a hook and loop fastener. In some embodiments, the fastener is a steel-aramid hook and loop fastener.

As identified above with respect to FIG. 2, several modules may be required to effectively heat an entire vapor deposition precursor delivery system. Accordingly, in some embodiments, a heater jacket for a vapor deposition precursor delivery system comprises more than one heater jacket module joined together to provide a plurality of physically interconnected heater jacket modules. Further, in some embodiments, where more than one heater jacket module is present, each heater jacket module may be joined by a fastener to another heater jacket module. In some embodiments, the fastener is a hook and loop fastener. In some embodiments, the fastener is a steel-aramid hook and loop fastener.

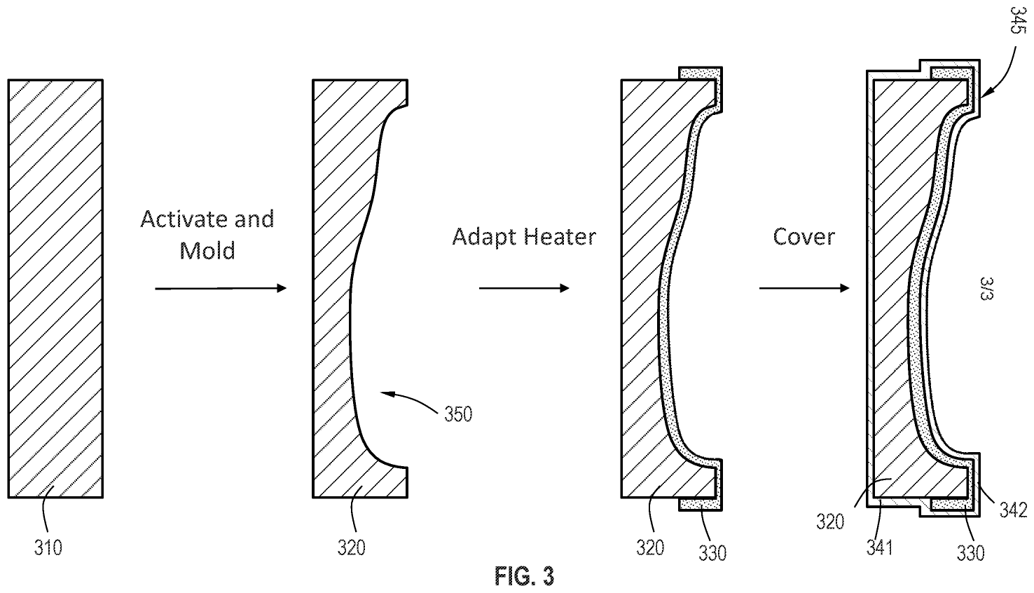

Additional embodiments of the disclosure relate to a method 300 of forming a heat jacket insulator. The methods may be understood with reference to FIG. 3. The method begins by activating a moldable insulator material 310. In some embodiments, the moldable insulator is in the shape of a sheet of material, such as a flat sheet of material. Described further above, the activated moldable insulator material 310 is capable of being conformed to a first shape 350 comprising a plurality of lines and/or an ampoule, as shown in FIGS. 1 and 2 other than the shape of the moldable insulator material 310. Still referring to FIG. 3, the activated moldable insulator material 310 is conformed to the first shape 350 corresponding to a first vapor deposition precursor delivery system or portion thereof (e.g., a first plurality of lines, valves, and/or connections). The resulting insulator is referred to as a first shape-conformed insulator 320. Then, the first shape-conformed insulator 320 is solidified and locked into the first shape. The solidification process removes the ability for the insulator to be further formed or shaped without reactivation so that the first shape-conformed insulator 320 can be re-formed into a second, different shape.

In some embodiments, the method further comprises forming a heating jacket module 345 comprising a flexible heating element 330 and cover, which as shown comprises a first insulator cover 341 and second heater cover 342. It will be understood that the first insulator cover 341 and the second heater cover 342 may comprise a single sheet or piece of cover material. The flexible heating element 330 is sized and shaped and therefore adapted to the first shape-conformed insulator 320. In so doing, the flexible heating element 330 conforms to the shape of the first shape-conformed insulator 320. Next, the first shape-conformed insulator and the flexible heating element are surrounded with a cover, for example, the first insulator cover 341 and the second heater cover 342.

As described above, the cover may be comprised of a first insulator cover and a second heater cover. The two portions of the cover may be fastened together. Accordingly, in some embodiments, surrounding the first shape-conformed insulator and the flexible heating element comprises covering the first shape-conformed insulator with a first cover; covering the flexible heating element with a second cover; and fastening the first cover and the second cover to surround the insulator and the heating element.

As above, the first cover and the second over may be fastened by a hook and loop fastener. Additionally, in some embodiments, the first cover and the second cover may be fastened with a steel-aramid hook and loop fastener.

Finally, the method may be repeated to reform the insulator into a different shape. In these embodiments, the first shape-conformed insulator is reactivated. The insulator is reformed to a second vapor deposition precursor delivery system or portion thereof (e.g., a second plurality of lines, valves, and/or connections) to form a second shape-conformed insulator. The second shape-conformed insulator is solidified. One skilled in the art will recognize that the second shape-conformed insulator can be further processed to form a second heat module as described above.

One or more embodiments described herein advantageously provide heater jacket modules and methods, which configured to conform to a wide variety of specific complex shapes. Further, the disclosed methods advantageously allow for the re-use of the insulator material in various different shapes as well as the flexible heating element and cover regardless of the shape of the vapor deposition precursor delivery system. In one or more embodiments, the heater jacket modules are configured to withstand temperatures as high as 300° C. Advantageously, the heater jacket modules and methods described herein fulfill a long-standing and pressing need that avoids required fabrication of customized heating jackets for different vapor deposition precursor delivery systems comprising complex shapes, which is a lengthy and expensive. The heater jacket modules and methods described herein provide highly efficient heating of vapor deposition precursor delivery systems comprising complex shapes, which can be reused and re-shaped multiple times, avoiding current practices that involve the use of expensive custom made heating jackets or a combination of heating tapes and insulating wrapping. The embodiments described herein avoids tedious and time-consuming unwrapping/wrapping of insulation and heating, which is prone to increased wear and detachment of thermocouples and fittings.

In addition, the heater jacket modules described herein fulfill a pressing need to be able to heat and insulate small diameter fittings and gas lines such as VCR fittings 162 and gas lines 160. The heater jacket modules 210 described according to one or more embodiments comprising the first shape-conformed insulator 320 enables the heater jacket module 210 to properly heat and contact small diameter gas lines having diameters between 1.8 and 15 mm.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A heater jacket module comprising:
a first layer including a moldable insulator material configured to conform to a shape of a plurality of lines, valves and/or fittings connected to a vapor deposition precursor delivery system;
a second layer over the first layer and including a flexible heating element configured to conform to the shape of the plurality of lines, valves and/or fittings; and
a third layer over the second layer and including an electrically insulting and flame retardant cover surrounding the flexible heating element and the moldable insulator.

2. The heater jacket module of claim 1, wherein the moldable insulator material comprises a reformable ceramic.

3. The heater jacket module of claim 2, wherein the reformable ceramic comprises a ceramic material that is capable of being activated, formed, solidified, reactivated, and reformed.

4. The heater jacket module of claim 1, wherein the flexible heating element comprises a carbon fiber cloth.

5. The heater jacket module of claim 4, wherein the flexible heating element further comprises electrodes and a controller connected to the electrodes and configured to control a temperature of the flexible heating element.

6. The heater jacket module of claim 5, wherein the controller is also connected to the plurality of lines, valves and/or fittings and is further configured to control the temperature of the flexible heating element in response to the temperature of the plurality of lines, valves and/or fittings.

7. The heater jacket module of claim 1, wherein the electrically insulting and flame retardant cover comprises aramid.

8. The heater jacket module of claim 1, wherein the electrically insulting and flame retardant cover comprises a heating cover and an insulating cover, the heating cover covering an exterior surface of the flexible heating element, the insulating cover covering an exterior surface of the moldable insulator.

9. The heating jacket module of claim 8, wherein the heating cover and the insulating cover are joined by a fastener.

10. The heating jacket module of claim 9, wherein the fastener is a steel-aramid hook and loop fastener.

11. A heater jacket comprising more than one heater jacket module of claim 1.

12. The heater jacket of claim 11, wherein the more than one heater jacket modules are joined by a steel-aramid hook and loop fastener.

13. A method of forming a heat jacket insulator, the method comprising:
activating a moldable insulator material;
conforming the moldable insulator material to a first plurality of lines, valves and/or fittings comprising a first shape to form a first shape-conformed insulator; and
solidifying the first shape-conformed insulator to the first shape.

14. The method of claim 13, further comprising:
conforming a flexible heating element to the first shape-conformed insulator; and
surrounding the first shape-conformed insulator and the flexible heating element with an electrically insulting and flame retardant cover to form a heating jacket module.

15. The method of claim 14, wherein the flexible heating element comprises a carbon fiber cloth.

16. The method of claim 14, wherein the electrically insulting and flame retardant cover comprises aramid.

17. The method of claim 14, wherein surrounding the shape conformed insulator and the flexible heating element with an electrically insulting and flame retardant cover comprises:
covering the shape-conformed insulator with a first cover;
covering the flexible heating element with a second cover; and
fastening the first cover and the second cover to surrounding the shape conformed insulator and the flexible heating element.

18. The method of claim 17, wherein the first cover and the second cover are fastened by a hook and loop fastener.

19. The method of claim 18, wherein multiple heating jacket modules are joined to form a heating jacket, each heating jacket module joined by a hook and loop fastener.

20. The method of claim 13, further comprising:
reactivating the first shape-conformed insulator;
reforming the shape-conformed insulator to a second plurality of lines, valves and/or fittings with a second shape to form a second shape-conformed insulator; and
solidifying the second shape-conformed insulator.
